(19) United States
(12) Patent Application Publication
(10) Pub. No.: US 2008/0286461 A1
(43) Pub. Date: Nov. 20, 2008

(54) VACUUM EVAPORATION METHOD

(76) Inventors: Yukihisa NOGUCHI, Kanagawa (JP); Makoto Kashiwaya, Kanagawa (JP)

Correspondence Address: BIRCH STEWART KOLASCH & BIRCH, PO BOX 747, FALLS CHURCH, VA, 22040-0747, US

(21) Appl. No.: 12/121,455

(22) Filed: May 15, 2008

(30) Foreign Application Priority Data
May 17, 2007 (JP) 2007-131164

(51) Int. Cl. C23C 16/00

(52) U.S. Cl. 427/248.1

(57) ABSTRACT

The vacuum evaporation method provides a heating element between an evaporation source of a film-forming material and a substrate; and forms a phosphor layer of an alkali halide-based phosphor on a surface of said substrate by vacuum evaporation while causing the heating element to generate heat at a temperature t (° C.) satisfying Formula (1):

T−200≦t<T (1)

where T is a boiling point (° C.) of the film-forming material. This method is capable of using the film-forming material making up the phosphor layer with higher efficiency owing to a heating element while preventing the substrate and the phosphor layer from being adversely affected by heat from the heating element.

### BACKGROUND OF THE INVENTION

The present invention relates to a vacuum evaporation method capable of improving the efficiency in using film-forming materials when manufacturing radiation image conversion panels or the like having a phosphor layer formed by means of vacuum evaporation.

Nowadays, phosphors that respond in various ways to exposure to radiation (e.g. X-rays, α-rays, β-rays, γ-rays, electron beams, and ultraviolet rays) are known and find use in medical and various other fields.

Upon exposure to radiation, certain types of phosphors known in the art accumulate part of the energy of the applied radiation and, in response to subsequent application of exciting light such as visible light, they emit photostimulated luminescence in an amount that is associated with the accumulated energy. These phosphors are called “stimulable phosphors” or “storage phosphors”.

A radiation image information recording and reproducing system is known that employs a radiation image conversion panel having a film of the stimulable phosphor. The system has already been commercialized by, fur example, FUJIFILM Corporation under the trade name of FCR (Fuji Computed Radiography).

In that system, a subject such as a human body is irradiated with X-rays or the like to record radiation image information about the subject on the conversion panel (more specifically, the stimulable phosphor layer). After the radiation image information is thus recorded, the conversion panel is scanned two-dimensionally with exciting light to emit photostimulated luminescence which, in turn, is read photoelectrically to yield an image signal. Then, an image reproduced on the basis of the image signal is output as the radiation image of the subject, typically to a display device such as a CRT (cathode ray tube) display or on a recording material such as a photosensitive material.

Phosphors that emit luminescence in the visible light region upon exposure to radiation are also known and used in scintillator panels. More specifically, a system is employed in which a radiation having passed through a subject is converted with a scintillator panel (which is also a radiation image conversion panel) to visible light, which is then converted with a photoelectric convertor such as a photodiode to charges, which are sequentially read out with a thin film transistor (abbreviated as “TFT”) to form a radiation image.

The conversion panel is typically prepared by the following method: Powder of a phosphor is dispersed in a solvent containing a binder and other necessary ingredients to make a coating solution, which is applied to a panel-shaped support (substrate) made of glass or a resin, with the applied coating being subsequently dried.

As described in JP 2002-181997 A, conversion panels are also known which are prepared by forming a phosphor layer on a substrate through vapor-phase film deposition techniques (vacuum film deposition techniques) such as vacuum evaporation and sputtering. The phosphor layer formed by such vapor-phase film deposition techniques has superior characteristics in that it is formed in vacuo and hence has low impurity levels and that being substantially free of any other ingredients than the phosphor as exemplified by a binder, the phosphor layer not only has small scatter in performance but also features very highly efficient luminescence.

Film-forming materials serving as phosphors and in particular stimulable phosphors in forming conversion panels may be often expensive. Therefore, enhancing the utilization efficiency of such film-forming materials is also very important to reduce the production costs.

Methods using heating elements as described in JP 08-53763 A and JP 2007-70646 A are known to improve the utilization efficiency of the film-forming materials (evaporation materials) when forming a film by the vapor-phase film deposition techniques.

The method disclosed in JP 08-53763 A involves, for example, providing two reflector plates between an evaporation source (crucible) where a film-forming material is heated to melt and a substrate in such a manner that the reflector plates are opposed to each other to prevent vapors of the film-forming material from diffusing toward other areas than the substrate, and carrying out vacuum evaporation with the reflector plates being heated above the melting point of the film-forming material.

JP 2007-70646 A discloses a method for preparing a (radiation image) conversion panel having a phosphor layer formed on a substrate by vacuum evaporation at a degree of vacuum of 0.1 to 10 Pa. This method involves providing heating elements (diffusion preventing wall members) preventing vapors of a film-forming material from diffusing toward other areas than the substrate between an evaporation source and the substrate as in the above case and forming the phosphor layer on the substrate with the heating element being kept at a temperature which is higher than that of the substrate but is lower than that of the evaporation source.

Provision of such heating elements enables vapors of a film-forming material likely to diffuse toward other areas than the substrate to be reflected by the elements being heated to achieve film deposition on the substrate with vapors of the film-forming material directly traveling from the evaporation source to the substrate and vapors reflected by the heating elements, thus making it possible to improve the efficiency in using the film-forming material.

### SUMMARY OF THE INVENTION

However, when applied to the formation of a phosphor layer for a conversion panel, the method as that described in JP 08-53763 A in which film deposition is carried out as heat is generated from the heating elements at a high temperature may cause the radiation heat from the heating elements to increase the temperature of the substrate and also that of the phosphor being formed, leading to quality deterioration of the substrate and the phosphor. As a result, conversion panels having desired characteristics may often not be obtained. Considering an increase in the substrate temperature, organic materials such as resins cannot be used for the substrate.

The film-forming material, when reaching the heating elements that generates heat at a temperature above its melting point, is re-evaporated to cause a vapor stream (evaporation stream) of the film-forming material to diffuse, which may result in cases where the effect of improving the utilization efficiency of the film-forming material is not fully achieved.

On the other hand, the method disclosed in JP 2007-70646 A can prevent the phosphor from changing its nature due to its temperature increase to manufacture a conversion panel having desired characteristics, but this method is not sufficient to use the film-forming material with high efficiency.

The present invention has been made to solve the above-mentioned conventional problems and an object of the present invention is to provide a vacuum evaporation method used in manufacturing a radiation image conversion panel having a phosphor layer formed on a substrate by vacuum evaporation with an alkali halide-based phosphor, this method being capable of using a film-forming material making up the phosphor layer with higher efficiency owing to a heating element while also preventing the substrate and the phosphor layer formed from being adversely affected by heat from the heating element.

In order to attain the object described above, the present invention provides a vacuum evaporation method comprising:

providing a heating element between an evaporation source of a film-forming material and a substrate, and

forming a phosphor layer of an alkali halide-based phosphor on a surface of the substrate by vacuum evaporation while causing the heating element to generate heat at a temperature t (° C.) satisfying Formula (1):

T−200≦t<T (1)

where T is a boiling point (° C.) of the film-forming material.

In the vacuum evaporation method of the present invention, the heating element preferably comprises, when seen from above, plates which are opposed to each other with respect to an outlet for vapors of the film-forming material from the evaporation source. It is also preferable that the heating element comprise, when seen from above, a cylinder which surrounds an outlet for vapors of the film-forming material from the evaporation source. The alkali halide-based phosphor preferably contains cesium bromide and more preferably further contains europium.

According to the present invention having the features as described above, a heating element for improving the utilization efficiency of a film-forming material used is provided between an evaporation source and a substrate when forming an alkali halide-based phosphor layer on the substrate by vacuum evaporation, and the temperature of the heating element (heat generation temperature) can be set at a lower, temperature than usual to prevent the temperature of the substrate and that of the phosphor formed thereon from increasing due to heat from the heating element, thus keeping the substrate and the phosphor layer from altering due to the temperature increase.

In addition, by setting the temperature of the heating element at a temperature which is lower than usual and falls within a range suitable for the alkali halide-based phosphor used, vapors which do not travel toward the substrate but is likely to diffuse can be more advantageously reflected by the heating element without unnecessary diffusion of the vapor stream (evaporation steam) of the film-forming material, whereby the film-forming material can be used with further improved efficiency.

### BRIEF DESCRIPTION OF THE DRAWINGS

FIGS. 1A and 1B are schematic views showing an embodiment of a vacuum evaporation apparatus used in implementing the vacuum evaporation method of the present invention;

FIG. 2 is a schematic view showing an example of a heating element that may be used in the vacuum evaporation method of the present invention;

FIG. 3A is a schematic front view showing another embodiment of the vacuum evaporation apparatus used in implementing the vacuum evaporation method of the present invention;

FIG. 3B is a side view of the vacuum evaporation apparatus shown in FIG. 3A;

FIG. 4 is a plan view schematically showing a thermal evaporating section of the vacuum evaporation apparatus shown in FIG. 3A; and

FIG. 5 is a graph showing the results in Examples of the present invention.

### DETAILED DESCRIPTION OF THE PREFERRED EMBODIMENTS

On the pages that follow, the vacuum evaporation method of the present invention is described in detail with reference to the preferred embodiments depicted in the accompanying drawings.

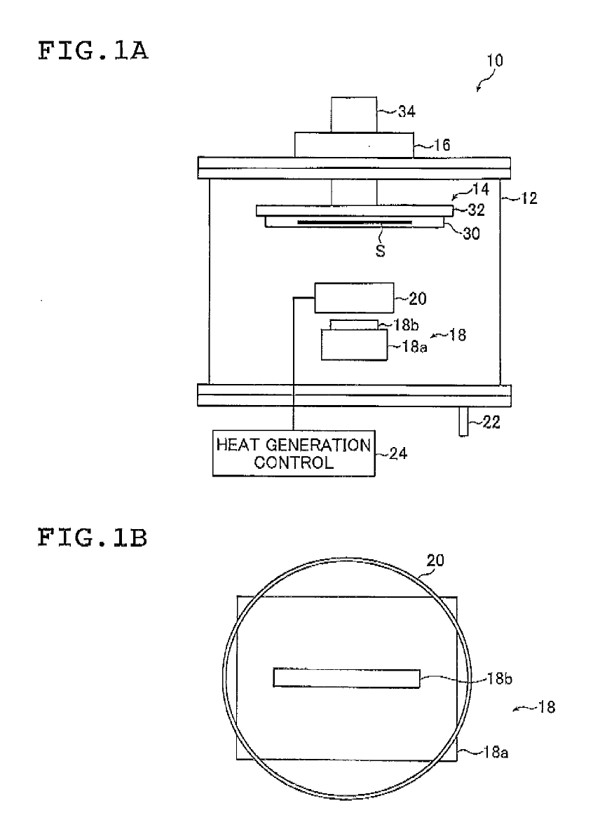

FIG. 1A schematically shows an embodiment of a vacuum evaporation apparatus used in implementing the vacuum evaporation method of the present invention.

A vacuum evaporation apparatus (hereinafter referred to as an “evaporation apparatus”) 10 shown in FIG. 1A is used to prepare a radiation image conversion panel (hereinafter referred to simply as a “conversion panel”) having a phosphor layer of an alkali halide-based phosphor formed by vacuum evaporation on the surface of a substrate S, and basically includes a vacuum chamber 12, a substrate holding means 14, a substrate rotating means 16, a crucible 19 serving as an evaporation source, a heating element 20, and a heat generation control means 24 for controlling heat generation from the heating element 20.

Needless to say, the evaporation apparatus 10 may optionally have various other components of known apparatuses for vacuum evaporation than the illustrated components, as exemplified by a shutter for blocking out vapors from the crucible 18.

There is no particular limitation on the substrate S used in the present invention but various types as used in conventionally known radiation image conversion panels are usable.

Exemplary types include plastic plates and sheets (films) made of, for example, cellulose acetate, polyester, polyethylene terephthalate, polyamide, polyimide, triacetate, and polycarbonate; glass plates and sheets made of, for example, quartz glass, alkali-tree glass, soda glass, heat-resistant glass (e.g., Pyrex™); metal plates and sheets made of metals such as aluminum, iron, copper and chromium and plates and sheets obtained by forming a coating layer such as a metal oxide layer on the surfaces of such metal plates and sheets.

If desired, the substrate S may have on its surface where the phosphor layer is to be formed, a protective layer for protecting the base body of the substrate S such as an aluminum plate, a reflective layer that reflects photostimulated luminescence, and even a protective layer that protects the reflective layer. In this case, the phosphor layer is formed on top of these layers.

In the present invention, on the above-mentioned substrate S is formed the phosphor layer of an alkali halide-based phosphor (alkali metal halide-based phosphor).

Various materials may be used for the alkali halide-based phosphor, but in terms of readily achieving the effects of the present invention and obtaining excellent photostimulated luminescence characteristics, alkali halide-based stimulable phosphors represented by the general formula “M^{I}X−aM^{II}X′₂·bM^{III}X″₃:cA” as disclosed in JP 61-72087 A are advantageously used. In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg, 0≦a<0.5, 0≦b<0.5, and 0<c≦0.2.

Of these, an alkali halide-based stimulable phosphor in which M^{I} contains at least Cs, X contains at least Br, and A is Eu or Bi is preferred, and a stimulable phosphor represented by the general formula “CsBr:Eu” is more preferred because they have excellent photostimulated luminescence characteristics and the effects of the present invention are advantageously achieved.

The present invention is not limited to the case where a (stimulable) phosphor layer comprising such a stimulable phosphor is formed in a stimulable (storage) phosphor panel (so-called imaging plate (abbreviated as IP)) where a radiation image of a subject is stored and recorded in the phosphor layer and exciting light is allowed to be incident on the phosphor layer to cause photostimulated luminescence corresponding to the recorded radiation image to be emitted therefrom, but the present invention may be used to form a phosphor layer comprising a phosphor which emits light fluorescence) in response to incidence of radiation as used in a scintillator panel or the like as long as the phosphor used is an alkali halide-based phosphor.

Various materials may be used for such phosphors as long as it is an alkali halide-based phosphor. Also in terms of readily achieving the effects of the present invention and obtaining excellent photostimulated luminescence characteristics, alkali halide-based phosphors represented by the general formula “M^{I}X·aM^{II}X′₂·bM^{III}X″₃:zA” are advantageously used. In this formula, M^{I} represents at least one alkali metal selected from the group consisting of Li, Na, K, Rb, and Cs. M^{II} represents at least one alkaline earth metal or divalent metal selected from the group consisting of Be, Mg, Ca, Sr, Ba, Ni, Cu, Zn and Cd. M^{III} represents at least one rare earth element or trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one halogen selected from the group consisting of F, Cl, Br, and I. A represents at least one rare earth element or metal selected from the group consisting of Y, Ce, Pr, Nd, Sm, Eu, Gd, Tb, Dy, Ho, Er, Tm, Yb, Lu, Na, Mg, Cu, Ag, Tl and Bi. 0≦a<0.5, 0≦b<0.5, and 0<z<1.0.

Of these, an alkali halide-based phosphor represented by the above general formula in which M^{I} contains Cs, X contains I, A contains Tl or Na, and 1×10⁻⁴≦z≦0.1 is preferred, and an alkali metal halide-based phosphor represented by the formula “CsI:Tl” is more preferably used.

The vacuum chamber 12 of the evaporation apparatus 10 is any known vacuum chamber (e.g. bell jar or vacuum vessel) that is formed of iron, stainless steel, aluminum, etc. and which is employed in apparatuses for vacuum evaporation.

Although not shown, an evacuation line including a main evacuation valve and a bypass line as well as a vacuum pump that may be used to evacuate the vacuum chamber are connected to the vacuum chamber 12. Various types of known vacuum pumps such as a rotary pump, an oil diffusion pump, a cryogenic pump and a turbo-molecular pump or combinations thereof may be employed without any particular limitation optionally in combination with a cryogenic coil.

The vacuum chamber 12 is provided with a gas introducing means 22 for introducing argon gas to adjust the degree of vacuum. The gas introducing means 22 is also a known gas introducing means that has a means of connection to a tank as well as a means for regulating the gas flow rate (the gas introducing means 22 may alternatively be connected to those means), and which may be employed in apparatuses for vacuum evaporation and sputtering.

The substrate holding means 14 includes a substrate holder 30, a holder mounting section 32 and a rotary shaft 34.

The substrate holder 30 accommodates and holds the substrate S with its film-forming area open to the crucible 18. Various types of substrate holder used in vacuum evaporation apparatuses or other vacuum film-forming apparatuses are all available for the substrate holder 30, as exemplified by a frame holding the four sides of the substrate S, and a casing which accommodates the substrate S and has an opening in the portion corresponding to the film-forming area. The substrate holder 30 may serve as a mask regulating the film-forming area on the surface of the substrate S where a film is formed. Alternatively, a mask may be separately provided.

In the illustrated case, the substrate holder 30 is detachably mounted at a predetermined position of the holder mounting section 32 by any known means such as a method using a fitting or engaging member. The holder mounting section 32 is a member in a disk shape and its back side is fixed to the lower end of the rotary shaft 34 in a cylindrical shape. The rotary shaft 34 is axially supported by the substrate rotating means 16.

In other words, by mounting the substrate holder 30 containing the substrate S on the holder mounting section 32 of the illustrated evaporation apparatus 10, the substrate S is loaded into the evaporation apparatus 10 at its predetermined position to be subjected to film formation by vacuum evaporation.

In the evaporation apparatus 10, the holder mounting section 32 may be provided on its lower surface with a heating means for heating the substrate S within the substrate holder 30 and a thermally conductive sheet for uniformly transmitting heat from the heating means to the substrate S.

The substrate holder 30 may also be provided on its inner surface with a thermally conductive sheet which is in close contact with the back surface of the substrate S opposite to the side where a film is formed to thereby uniformly transmit heat from the heating means in the holder mounting section 32 to the substrate S.

As described above, the back side of the holder mounting section 32 is fixed to the rotary shaft 34, which, in turn, is axially supported by the substrate rotating means 16.

The substrate rotating means 16 rotates the rotary shaft 34, that is, the holder mounting section 32 at a predetermined speed (rotational speed). Therefore, the substrate S within the substrate holder 30 which is fixed to the holder mounting section 32 is rotated at the predetermined speed by means of the substrate rotating means 16.

The vacuum evaporation method of the present invention is not limited to one in which a phosphor layer is formed by vacuum evaporation as the substrate S is being rotated. A phosphor layer may be formed by vacuum evaporation as the substrate S is fixed, or as will be described later, be formed by vacuum evaporation as the substrate S is linearly reciprocated.

The crucible 18 serving as the evaporation source in the illustrated evaporation apparatus 10 is a crucible for resistance heating. In other words, the evaporation apparatus 10 heats to evaporate the film-forming material by resistance heating. The crucible 18 is disposed by any known means at a predetermined position within the vacuum chamber 12.

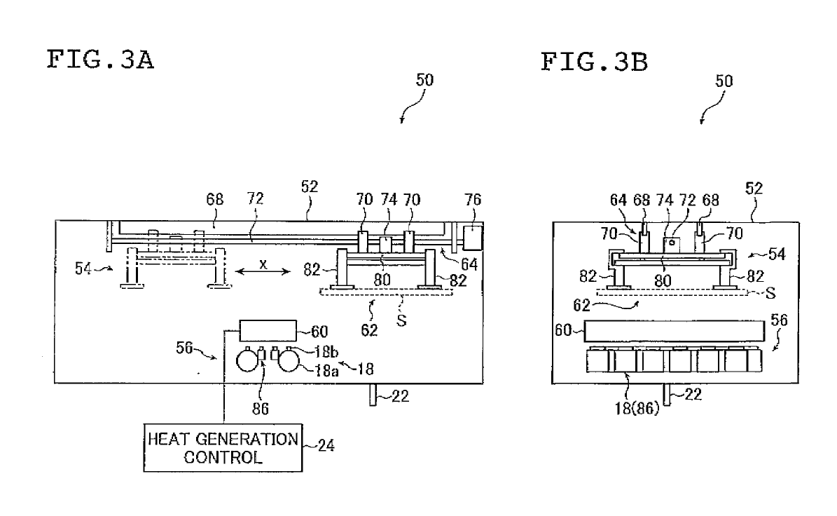

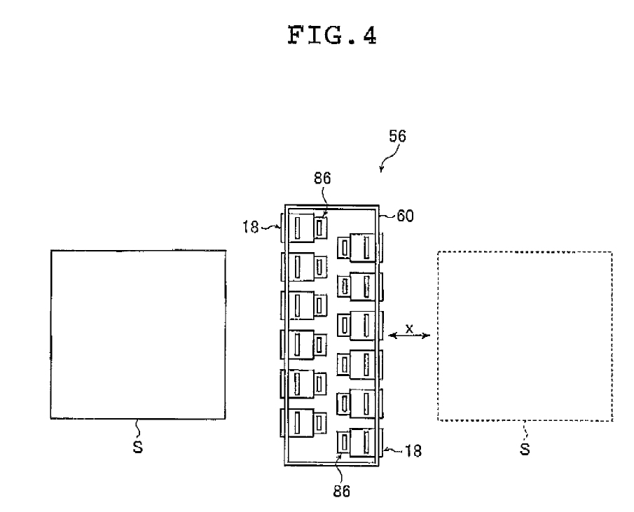

The illustrated crucible 18 includes a hollow cylindrical crucible body 18a having a rectangular vapor outlet (vapor discharge port) and a chimney 18b in the shape of a quadrangular prism which surrounds the vapor outlet and projects from the crucible body 18a (see also FIGS. 3A, 3B and 4). The vapor outlet has an elongated rectangular shape extending along the center line of the cylinder.

Although not shown, the crucible 18 (more specifically crucible body 18a) may be connected to a power supply for resistance heating and be provided with a means for measuring the temperature of the film-forming material (crucible 18) as exemplified by a thermocouple.

In the present invention, the crucible serving as the evaporation source is not limited to one having the above-mentioned structure, and various types of crucibles including so-called boat-type crucibles and cylindrical or cup-type crucibles that open at their upper ends are all available.

The crucible 18 for resistance heating is not the sole means used as the evaporation source and heating means, and various evaporation sources that may be used in vacuum evaporation are all available as long as induction heating and electron beam (EB) heating can be used in accordance with the film-forming conditions such as the degree of vacuum upon vapor deposition.

The heating element 20 is provided above the crucible 18. In the illustrated case, the heating element 20 is made of a material generating heat by application of current as exemplified by tungsten, tantalum, molybdenum or carbon and is connected to the heat generation control means 24 which applies current to the heating element 20 for heat generation.

The heating element 20 generates heat at a predetermined temperature to cause the vapors of the film-forming material traveling from the crucible 18 toward other areas than the substrate S (vapor stream) to be reflected by the heating element 20 to be directed toward the substrate S, thereby improving the efficiency of the film-forming material used.

As described above, the heating element 20 generates heat by application of current from the heat generation control means 24.

In the present invention, an alkali halide-based phosphor is used as the film-forming material and the heating element 20 is caused to generate heat at a temperature t [° C.] satisfying Formula (1) below:

T−200≦t<T (1)

where T is the boiling point (° C.) of the film-forming material used.

More specifically, in the present invention, an alkali halide-based phosphor is used as the film-forming material and the heating element 20 is caused to generate heat within the range of temperatures lower by up to 200° C. than the melting point of the film-forming material.

It is known in vacuum evaporation that a heating element (hot wall) is provided between an evaporation source and a substrate to reflect the vapor stream flowing to the other areas than the substrate toward the substrate, thus improving the utilization efficiency of the film-forming material. In conventional vacuum evaporation making use of such heating element, as is also described in JP 08-53763 A, the heating element is heated to a temperature above the melting point of the film-forming material, and it has been considered that this method enables vapors flowing to other areas than the substrate to be reflected by the heating element toward the substrate, thus improving the efficiency of the film-forming material used.

According to the investigations made by the inventors, however, it has been found that, in the case of forming a phosphor layer of an alkali halide-based phosphor, generation of heat from the heating element at such a temperature may elevate the temperature of the substrate or the phosphor due to radiation heat from the heating element, thus causing quality deterioration. In addition, a material having a low heat resistance such as a resin material cannot be used for the substrate, because the substrate is heated to a high temperature.

It has also conventionally been considered that the heating element heated to a temperature not lower than the melting point of the film-forming material ensures reflection of the vapors to improve the efficiency of the film-forming material used. According to the investigations made by the inventors, however, at a heating element temperature not lower than the melting point of the film-forming material, the film-forming material is brought into the state in which it is re-evaporated, resulting in diffusion of the vapor stream and insufficiently improved efficiency in using the film-forming material. On the contrary, the amount of vapors reaching the substrate may often decrease to lower the efficiency of the film-forming material used.

On the other hand, the phosphor layer and the substrate can be protected against quality deterioration by forming the phosphor layer on the substrate while, as disclosed in JP 2007-70646 A, the heating element (diffusion preventing wall member) is kept at a temperature which is higher than that of the substrate but is lower than that of the evaporation source. Nevertheless, this condition causes deposition of the film-forming material onto the heating element and is not sufficient to achieve high efficiency in using the film-forming material.

In view of this, when an alkali halide-based phosphor layer is formed by vacuum evaporation in the present invention, the heating element 20 is caused to generate heat at a temperature lower by up to 200° C. than the melting point of the film-forming material. In other words, the heating element 20 is caused to generate heat at a temperature which is lower than that used in common vacuum evaporation and is appropriate to the melting point of the film-forming material.

Such a structure enables a less heat-resistant material such as a resin material to be used for the substrate S while preventing the substrate S and the phosphor layer from being heated by the radiation heat from the heating element 20 causing quality deterioration. Within this temperature range, vapors of the alkali halide-based phosphor used as the film-forming material are appropriately reflected by the heating element 20 while causing no re-evaporation, thus enabling the utilization efficiency of the film-forming material to be more advantageously improved.

When the heating element 20 has a temperature not lower than the melting point of the film-forming material in the present invention, there arise deterioration of the phosphor layer or other defects as seen in conventional vacuum evaporation processes which involve heating the heating element to a high temperature. At a temperature of the heating element 20 which is lower by more than 200° C. than the melting point, the film-forming material deposits on the heating element to lower the utilization efficiency of the film-forming material. Further, particles falling from the heating element may enter the evaporation source to cause bumping or deterioration of the characteristics of the phosphor.

In the present invention, the heat generation temperature of the heating element 20 is preferably in the range from the temperature lower by 200° C. than the melting point of the film-forming material to the temperature lower by 30° C. than its melting point. Within the above-defined temperature range, adverse effects of the heat generation from the heating element 20 can be more reliably avoided while vapors of the film-forming material are more advantageously reflected by the heating element 20, making it possible to further improve the utilization efficiency of the film-forming material.

There is no particular limitation on how the heat generation control means 24 controls the heat generation temperature of the heating element 20 and various known methods may be used.

For example, a feedback control system may be used in which any known temperature measuring means such as a thermocouple or a radiation thermometer (radiation pyrometer) is used to measure the temperature of the heating element 20 and its temperature is controlled in accordance with the temperature measurement results. Alternatively, the temperature of the heating element 20 may be controlled based on the relation between the amount of electricity to the heating element 20 and the temperature of the heating element 20 that has been determined beforehand by an experiment or a simulation.

In the present invention, the temperature of the heating element 20 is not necessarily constant but may vary within the above-defined range.

In the illustrated evaporation apparatus 10, as shown in FIGS. 1A and 1B, the heating element 20 is in the shape of a cylinder with its upper and lower sides open. In a preferred embodiment, the heating element 20 is disposed just above the chimney 18b of the crucible 18 so that the chimney 18b (outlet of the film-forming material's vapors) is positioned within the lower surface of the heating element 20 when seen from the upper surface side of the heating element 20 (from above in the vertical direction).

Such a layout enables vapors flowing to other areas than the substrate S to be more reliably reflected by the heating element 20, thus more advantageously improving the utilization efficiency of the film-forming material.

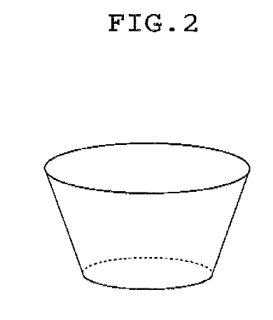

In the present invention, the heating element 20 is not limited to one having a cylindrical shape, but one having a cylindroid or prism shape may be used. In addition, the heating element 20 is not limited to one having the shape of a straight tube whose diameter does not change, and may be, for example, in such a shape as to enlarge (increase in diameter) toward the substrate S (upward) in accordance with the diffusion of the vapors toward the substrate S as in the shape of an inverted cone (frustum) shown in FIG. 2.

The shape of the heating element 20 is not limited to a columnar shape.

For example, the heating element may comprise a plurality of planar or curved sheets disposed so as to surround the vapor outlet of the evaporation source when seen from above. Alternatively, a pair of planar or curved sheets may be used for the heating element which are disposed so as not to surround the vapor outlet but to prevent vapors from diffusing toward other directions than the direction in which the substrate is located, and are opposed to each other with the vapor outlet of the evaporation source disposed therebetween when seen from above. The utilization efficiency of the film-forming material can also be improved by using a single planar or curved sheet depending on how the vapors flow.

The heating element 20 in the illustrated case is made of a material such as tungsten that generates heat by application of current. However, this is not the sole case of the present invention, but various arrangements are available as long as heat generation at or heating to a desired temperature is possible.

For example, heating elements which do not generate heat may be used, as exemplified by a tube or plate that has a heater or other heating means incorporated within the wall, or a tube or plate that has a heater or other heating means held in contact with its surface which does not come in contact with the vapors of the film-forming material.

In other words, there is no particular limitation on the shape, size and layout of the heating element 20, and various types are available as long as they prevent the vapors from flowing toward other portions than the substrate S. The shape, size and layout of the heating element 20 may be determined as appropriate for the size of the vapor outlet of the evaporation source, the size of the substrate S, and the distance between the evaporation source and the substrate S.

In particular, it is preferable when seen from above that the lower end portions of the heating element be opposed to each other with the vapor outlet of the evaporation source disposed therebetween. The heating element is more preferably in the shape of a cylinder whose lower end surrounds the vapor outlet of the evaporation source.

The lower end of the heating element is preferably located just above the vapor outlet of the evaporation source. It is also preferable for the lower end of the heating element to be located below the vapor outlet of the evaporation source so that the heating element encloses the vapor outlet of the evaporation source.

The illustrated evaporation apparatus 10 has only one crucible 18 disposed therein. However, this is not the sole case of the present invention, but the evaporation apparatus 10 may have a plurality of evaporation sources (crucibles).

In the case of using a plurality of evaporation sources, a single source vacuum evaporation in which all the evaporation sources are filled with a single film-forming material, or a multi-source vacuum evaporation in which the evaporation sources are filled with different film-forming materials may be applied.

In the case where the vacuum evaporation method of the present invention is applied to such vacuum evaporation using a plurality of evaporation sources, a heating element may be provided for each evaporation source or for an appropriately set number of evaporation sources. Alternatively, a single heating element may be provided for all the evaporation sources.

The present invention is not limited to the above-mentioned case in which the phosphor layer is formed by vacuum evaporation as the substrate S is rotated. The phosphor layer may be formed as the substrate S is fixed or reciprocated.

FIG. 3A is a front view schematically showing another embodiment of the vacuum evaporation apparatus to which the vacuum evaporation method of the present invention is applied to form the phosphor layer on the substrate S being reciprocated. This is a view seen from a direction orthogonal to the direction in which the substrate S to be described later travels (direction indicated by an arrow “x”). FIG. 3B is a side view of the vacuum evaporation apparatus shown in FIG. 3A and is a view seen from the direction in which the substrate S to be described later travels.

A vacuum evaporation apparatus (hereinafter referred to simply as an “evaporation apparatus”) 50 has the same components as those of the aforementioned evaporation apparatus 10, so the same components are denoted by the same reference numerals and the following description mainly focuses on the distinctive features of the evaporation apparatus 50.

This evaporation apparatus 50 also forms the phosphor layer on the surface of the substrate S by vacuum evaporation. An shown in FIG. 3A, the evaporation apparatus 50 basically includes a vacuum chamber 52, a substrate transport mechanism 54, a thermal evaporating section 56 and a gas introducing means 22.

FIG. 4 shows a top view (plan view) of the thermal evaporating section 56, but as shown in FIGS. 3A, 3B and 4, the thermal evaporating section 56 is provided with a heating element 60 which is open at its upper and lower sides and is in the shape of a quadrangular prism. To the heating element 60 is connected a heat generation control means 24 of the same type as described above (not shown in FIGS. 3B and 4).

Needless to say, the evaporation apparatus 50 may optionally have various other components of known apparatuses for vacuum evaporation than the illustrated components, as exemplified by a shutter for blacking out vapors from the evaporation sources.

In a preferred embodiment of the illustrated evaporation apparatus 50, two-source vacuum evaporation in which film-forming materials, one for a phosphor (matrix) and the other for an activator are separately evaporated is applied to form a (stimulable) phosphor layer on the surface of the substrate S being linearly reciprocated to thereby produce a conversion panel.

For example, in the case of CsBr:Eu illustrated above as a preferred stimulable phosphor, cesium bromide (CsBr) and europium bromide [EuBrₓ (x is typically 2 to 3, with 2 being preferred)] are used as the film-forming materials for the phosphor and the activator component, respectively, and two-source vacuum evaporation in which these materials are charged into different evaporation sources and independently heated to evaporate is performed to form a phosphor layer of the phosphor CsBr:Eu on the substrate S.

The vacuum chamber 52 of the evaporation apparatus 50 is a known vacuum chamber of the same type as the vacuum chamber 12. The gas introducing means 22 is also of the same type as that in the above-mentioned embodiment.

The substrate transport mechanism 54 holds the substrate S and transports the held substrate S to-and-fro on a linear transport path, and includes a substrate holding means 62 and a transport means 64.

The transport means 64 is a known mechanism for effecting linear movement making use of screw transmission, which includes a linear motor guide having guide rails 68 and engagement members 70 guided by engagement with the guide rails 68, a ball screw having a screw shaft 72 and a nut 74, and a rotary drive source 76 for the screw shaft 72. The rotary drive source 76 is capable of forward/reverse rotation.

On the other hand, the substrate holding means 62 has a base 80 and holding members 82.

The base 80 is a rectangular plate member, to the upper surface of which are secured the nut 74 and the engagement members 70 of the transport means 64. The holding members 82 are secured to the base 80 so as to suspend from four corners of the base 80, thereby holding the substrate S at their lower ends. There is no particular limitation on the method of holding the substrate S with the holding members 82, but any known method of holding plate members is available.

The substrate holding means 62 is linearly moved by the transport means 64 in a specified direction (direction indicated by the arrow “x” in FIGS. 3A and 4, and direction perpendicular to the paper in FIG. 3B).

In the illustrated evaporation apparatus 50, the rotary drive source 76 is driven to rotate the screw shaft 72 with the substrate S held by the substrate holding means 62, causing the transport means 64 to transport the substrate holding means 62 to enable linear reciprocating movements of the substrate S. As will be described later, the illustrated embodiment achieves formation of a phosphor layer with a highly uniform film thickness profile by linearly transporting the substrate S as described above while a plurality of evaporation sources are arranged in a direction perpendicular to the transport direction of the substrate S.

The number of times the reciprocating movements are made may be determined as appropriate for the thickness of the phosphor layer to be formed and the transport speed of the substrate S. The speed at which the substrate S is transported may also be determined as appropriate for the transport speed limit of the apparatus, the number of times the reciprocating movements are made, and the phosphor layer thickness to be achieved.

In the present invention, the substrate holding means 62 is not limited to one having the above-mentioned layout, but any known means for linearly reciprocating a plate is available.

The thermal evaporating section 56 is provided at the bottom of the vacuum chamber 12.

The thermal evaporating section 56 uses, for example, crucibles for resistance heating as evaporation sources to heat to evaporate film-forming materials by resistance heating.

As described above, the illustrated evaporation apparatus 50 forms a phosphor layer by two-source vacuum evaporation in which a film-forming material for a phosphor and a film-forming material for an activator are heated to evaporate independently of each other. For this type of vacuum evaporation, the thermal evaporating section 56 has two types of crucibles including crucibles 18 that serve as evaporation sources of a film-forming material fox a phosphor and crucibles 86 that serve as evaporation sources of a film-forming material for an activator.

The evaporation source 18 for a phosphor includes a crucible body 18a and a chimney 18b as in the first embodiment. On the other hand, the crucible 86 for an activator is of a commonly used boat type having an upper surface closed by a cover with a rectangular vapor outlet, and a chimney of the same type as above which is in the shape of a quadrangular prism and has open upper and lower surfaces is provided so as to surround the vapor outlet.

In the stimulable phosphor, the proportion of the activator to the phosphor is such that the greater part of the phosphor layer in assumed by the phosphor, as exemplified by a molarity ratio ranging from about 0.0005/1 to about 0.01/1. The crucible 86 for the activator may be of a much smaller size than the evaporation source 18 for the phosphor.

As shown in the schematic plan view of FIG. 4, a pair of a crucible 18 and a crucible 86 are disposed side by side in the direction in which the substrate S is reciprocated. The respective crucibles are insulated from each other by spacing them apart from each other or inserting an insulating material.

Six crucible pairs each including one crucible 18 and one crucible 86 are disposed in a direction perpendicular to the direction in which the substrate S is reciprocated. The evaporation apparatus 50 has two rows of the crucible pairs disposed in the direction of reciprocating movement, each crucible row extending in the direction perpendicular to this direction of reciprocating movement, which is hereinafter referred to as “alignment direction” for the sake of convenience. In addition, the two rows of the crucible pairs are disposed such that the crucible pairs in one row and those in the other row are staggered in the alignment direction to fill the gaps between adjacent crucibles in the alignment direction thereby enabling more uniform emission of the film-forming material vapors in the alignment direction.

Vacuum evaporation is carried out in the illustrated evaporation apparatus 50 as the substrate S is linearly reciprocated and this ensures that the linear velocity over the surface of the substrate S (where the phosphor layer is to be deposited) is made uniform across this surface; in addition, a plurality of crucibles (evaporation sources) are disposed in the direction perpendicular to the direction of reciprocating movement, enabling the substrate S to be exposed to a more uniform amount of vapors in this alignment direction. With this extremely simple arrangement of evaporation sources, the entire surface of the substrate S can be uniformly exposed to the vapors of the film-depositing materials, which contributes to the formation of a phosphor layer having high uniformity in thickness profile. The beneficiary effects of these features are particularly significant when vacuum evaporation is performed under a medium degree of vacuum as will be described later, where in order to minimize the collision between the gas particles of argon or other inert gas and the evaporated film-depositing material, the gap between the substrate and each crucible must be made smaller than in the case of ordinary deposition which is effected under high vacuum but then the vapors of the film-depositing material will directly reach the substrate S before they have sufficiently diffused within the evaporation system.

The features described above offer the additional advantage of allowing the activator component to be dispersed most uniformly within the stimulable phosphor layer in both directions of its plane and thickness, whereby one can produce a conversion panel having good uniformity in various characteristics such as sensitivity and photostimulated luminescence characteristics.

The heating element 60 is disposed in the thermal evaporating section 56.

The heating element 60 in the illustrated embodiment is a member in the shape of a quadrangular prism which is used for all the evaporation sources including the crucibles 18 and the crucibles 86, surrounds the chimneys of all the crucibles (vapor outlets of all the evaporation sources) when seen from the upper side, and has open upper and lower surfaces. The heating element 60 used may be of the same type as the heating element 20 of the above-mentioned evaporation apparatus 10.

As in the heating element 20, the heat generation control means 24 causes the heating element 60 to generate heat at the temperature t [° C.] satisfying Formula (1) below:

T−200≦t<T (1)

where T is the boiling point (° C.) of the film-forming material used.

In other words, the heating element 60 is caused to generate heat within the range of temperatures lower by up to 200° C. than the melting point of the film-forming material.

As in the first embodiment, the utilization efficiency of the film-forming material can be improved by using such a heating element 60, and the substrate S and the phosphor layer formed thereon can also be protected from deterioration due to heat in spite of the use of the heating element 60 for improving the utilization efficiency of the film-forming material.

A phosphor layer having a uniform thickness can be formed by vacuum evaporation on the substrate being reciprocated, but in order to form a phosphor layer with a more uniform thickness, it is preferable to prevent the film-forming material vapors from diffusing in the direction in which the substrate S is transported. The illustrated embodiment uses the heating element having walls which extend in the alignment direction and block out vapors likely to diffuse in the transport direction to advantageously prevent the vapors from diffusing in the transport direction, thus enabling a phosphor layer with a more uniform thickness to be formed.

Two-source vacuum evaporation in which a film-forming material for a phosphor and another film-forming material for an activator are separately heated to evaporate is carried out in the illustrated evaporation apparatus 50, and the single heating element 60 is used for all the evaporation sources.

In the case where the single heating element is used for evaporation sources containing a plurality of film-forming materials (in the case of multi-source vacuum evaporation and the case of using a plurality of film-forming materials as a mixture), the common temperature range is detected from the ranges of temperatures lower by up to 200° C. than the melting points of all the film-forming materials or some of them used in larger amounts.

Alternatively, the temperature of the heating element may be set based on the melting point of the film-forming material whose content in the phosphor layer is the largest (film-forming material whose amount of vapor deposition in the phosphor layer is the largest). As described above, in the case of a stimulable phosphor, the greater part of the phosphor layer is assumed by the phosphor, so the temperature for the heat generation from the heating element 60 may be set in accordance with the melting point of the film-forming material for the phosphor component. In other words, in the case of forming the phosphor layer of CsBr:Eu using cesium bromide and europium bromide, the temperature of the heating element may be set in accordance with the melting point (636° C.) of cesium bromide used as the film-forming material for the phosphor component.

As described above, in the case where a plurality of evaporation sources are used, the vacuum evaporation method of the present invention is not limited to one in which a single heating element is used for all the evaporation sources.

Therefore, for example, a total of 24 heating elements may be provided for the respective crucibles used in the illustrated evaporation apparatus 50, that is, the crucibles 18 and 86. Alternatively, a total of 12 heating elements may be provided so that one heating element corresponds to one crucible pair including a crucible 16 and a crucible 86, or a total of 2 heating elements may be provided so that one heating element corresponds to a row of evaporation sources in the alignment direction.

As described above, in the case where vapor deposition on the substrate is carried out as it is reciprocated, it is preferable to minimize the diffusion of the vapors not in the alignment direction but in the transport direction indicated by the arrow “x”.

The utilization efficiency of the film-forming materials can be advantageously improved by providing two heating plates apart from each other in the transport direction so as to sandwich the vapor outlet therebetween when seen from above.

The vacuum evaporation method of the present invention is described in greater detail by referring to the operation of the evaporation apparatus 10 shown in FIGS. 1A and 1B.

First, the substrate holder 30 containing the substrate S is mounted on the holder mounting section 32 at its predetermined position and the crucible 18 is charged with a predetermined amount of film-forming material.

Then, the vacuum chamber 12 is closed and evacuated by the vacuum pump to a predetermined degree of vacuum.

If the phosphor layer comprising an alkali halide-based phosphor, in particular, an alkali halide-based stimulable phosphor, more specifically, a stimulable phosphor represented by CsBr:Eu, is to be formed, a preferred procedure comprises first evacuating the system to a high degree of vacuum, then introducing an argon gas, a nitrogen gas or the like into the system to achieve a degree of vacuum between about 0.01 Pa and 3 Pa (which is hereinafter referred to as medium vacuum for the sake of convenience), and heating the film-forming material by resistance heating or the like to perform vacuum evaporation under such medium vacuum.

In most cases, the phosphor layer formed by vacuum evaporation and comprising a stimulable phosphor has a columnar crystal structure, and the phosphor layer that is formed by performing film deposition under such medium vacuum, in particular, the phosphor layer comprising the alkali halide-based stimulable phosphor such as CsBr:Eu has an especially satisfactory columnar crystal structure and is preferred in such terms as the photostimulated luminescence (PSL) characteristics and the sharpness of the image that can be produced.

When the vacuum chamber 12 has reached a predetermined degree of vacuum, an electric current is applied to the crucible 18 (the above-mentioned crucible for use in resistance hearing) to start heating the film-forming material and the substrate S is optionally rotated by the substrate rotating means 16.

At the point in time when the film-forming material (crucible 18) has reached a predetermined temperature, the shutter is opened to start formation of the phosphor layer on the substrate S.

In the evaporation apparatus 10 with which the vacuum evaporation method of the present invention is implemented, prior to starting vapor deposition of the phosphor layer on the substrate S, the heat generation control means 24 applies an electric current to the heating element 20 so that the phosphor layer is formed on the substrate S as the heating element 20 generates heat at a temperature t [° C.] satisfying Formula (1) below:

T−200≦t<T (1)

where T is the boiling point (° C.) of the film-forming material used.

In other words, the phosphor layer is formed on the substrate $ while the heating element 20 is caused to generate heat within the range of temperatures lower by up to 200° C. than the melting point of the film-forming material.

Therefore, the vapors of the film-forming material traveling toward other areas than the substrate S is reflected by the heating element 20 to be directed toward the substrate S, thereby improving the efficiency of the film-forming material used, while simultaneously having no deterioration of the substrate S or the phosphor layer due to heat in spite of the use of the heating element 20 for improving the utilization efficiency of the film-forming material. A proper phosphor layer can be thus formed while using the film-forming material with high efficiency.

There is no particular limitation on the timing at which the heating element 20 is caused to generate heat, but it is preferable to cause the heating element 20 to generate heat until the heating element 20 (or its heat generation) stabilizes at a desired temperature before definitively starting to heat the film-forming material in the crucible 18 (evaporation source) with the heat generation from the heating element 20 maintained.

This method enables proper check and control of the heat generation temperature of the heating element 20.

When the phosphor layer with a predetermined thickness has been formed, heating of the crucible 18 and heat generation from the heating element 20 are stopped. When the substrate S is rotated, the rotation is stopped, the vacuum chamber 12 is restored to atmospheric pressure and opened, and the substrate S having the phosphor layer formed thereon (i.e., conversion panel) is taken out from the vacuum chamber 12.

The thickness of the phosphor layer (film thickness) may be controlled by the film deposition rate corresponding to the predetermined heating conditions or based on the film thickness directly measured with a displacement gauge or other instrument. Alternatively, the film thickness may be controlled with a meter for measuring the quantity of evaporation using a crystal oscillator or the like.

While the vacuum evaporation method of the present invention has been described above in detail, the present invention is by no means limited to the foregoing embodiments and it should be understood that various improvements and modifications can of course be made without departing from the scope and spirit of the invention.

### EXAMPLES

### Example 1

The evaporation apparatus 10 shown in FIGS. 1A and 1B was used to form a phosphor layer on the substrate S.

A tantalum crucible for resistance heating was used for the crucible 18 and a type R (platinum-rhodium) thermocouple was inserted into and fixed to the crucible 18. The upper surface of the chimney 18b (i.e., vapor outlet) was in the shape of a rectangle with a size of 8 mm×60 mm.

The crucible 18 (more specifically the crucible body 18a) was charged with 600 g of powder of cesium bromide (CsBr having a melting point of 636° C.).

A cylinder made of tungsten which has an outer diameter of 80 mm, a height of 60 mm and a plate thickness of 0.2 mm and whose upper and lower surfaces are open was fixed as the heating element 20 at a position of 0 mm just above the crucible 18 (upper end of the chimney 18b), in other words, at a position at which the upper end of the chimney 18b was flush with the lower end of the heating element 20). As shown in FIG. 1B, the heating element 20 was disposed so as to surround the chimney 18b when seen from above.

In addition, a power supply for resistance heating was connected to both ends in the diameter direction of the heating element 20. The type R thermocouple was brought into contact with the outer wall surface, then pressed by a spring against the outer wall surface for fixing.

Then, a glass substrate with a size of 200 mm×200 mm and a thickness of 1.8 mm which served as the substrate S was placed in the substrate holder 30 and the substrate holder 30 containing the substrate S was mounted on the holder mounting section 32.

The substrate holder 30 was set such that the substrate S lay on the vertical line above the evaporation source 19 (chimney 18b) and was spaced apart from the crucible 18 by 150 mm.

Thereafter, the vacuum chamber 12 was closed and a main evacuation valve was opened to evacuate the vacuum chamber 12. A combination of a rotary pump, a mechanical booster pump and a diffusion pump was used for the vacuum pump (vacuum pumping system) together with a cryogenic pump for water discharge.

At the point in time when the vacuum chamber 12 had reached a degree of vacuum of 2×10⁻³ Pa, the main evacuation valve was closed to switch the evacuation to bypass mode and argon gas was introduced into the vacuum chamber 12 using the gas introducing means 22 to adjust the degree of vacuum in the vacuum chamber 12 to 1 Pa.

Then, an electric current of 280 A was applied to the heating element 20 to measure its temperature with the type R thermocouple pressed thereagainst. When the temperature measurement results from the type R thermocouple indicated that the temperature of the heating element 20 was made constant, an electric current was applied to the crucible 18 and the temperature measurement results from the type R thermocouple inserted into the crucible 18 was used to perform feedback control such that the temperature within the crucible 18 was kept constant at 670° C.

The heating element 20 had a temperature of 469° C.

At the point in time when the crucible 18 had stabilized at a temperature of 670° C., the shutter (not shown) was opened to start formation of the phosphor layer (cesium bromide layer) on the substrate S.

After 90 minutes had elapsed from the start of formation of the cesium bromide layer, application of the electric current to the crucible 18, then to the heating element 20, and also introduction of the argon gas were stopped.

Thereafter, the vacuum chamber 12 was opened to air to take the substrate S having the phosphor layer formed thereon and the crucible 18 out of the vacuum chamber 12.

The amount of the phosphor layer formed on the substrate S, that is, the amount (weight) of cesium bromide deposited onto the substrate S, and the amount (weight) of cesium bromide within the crucible 18 were measured, and the material utilization efficiency (amount of CsBr deposited onto the substrate S/(600—amount of CsBr within the crucible) was calculated from the above measurement results and the amount (600 g) of cesium bromide charged into the crucible 18.

As a result, a material utilization efficiency of 59.8% was obtained.

### Examples 2 and 3

Example 1 was repeated except that an electric current of 250 A was applied to the heating element 20 to heat it to a temperature of 443.5° C. (in Example 2) and that an electric current of 380 A was applied to the heating element 20 to heat it to a temperature of 568° C. (in Example 3), thereby forming a phosphor layer (cesium bromide layer) on the substrate S. Then, the material utilization efficiency was calculated.

As a result, a material utilization efficiency of 57.2% was obtained for each case.

### Comparative Examples 1 to 5

Example 1 was repeated except that an electric current of 80 A was applied to the heating element 20 to heat it to a temperature of 218.7° C. (in Comparative Example 1), an electric current of 150 A was applied to the heating element 20 to heat it to a temperature of 323.4° C. (in Comparative Example 2), an electric current of 215 A was applied to the heating element 20 to heat it to a temperature of 359.4° C. (in Comparative Example 3), an electric current of 230 A was applied to the heating element 20 to heat it to a temperature of 409.2° C. (in Comparative Example 4), and an electric current of 450 A was applied to the heating element 20 to heat it to a temperature of 734.8° C. (in Comparative Example 5), thereby forming a phosphor layer (cesium bromide layer) on the substrate S. Then, the material utilization efficiency was calculated.

As a result, Comparative Examples 1, 2, 3, 4 and 5 showed material utilization efficiencies of 26.4%, 24.9%, 34.3%, 45.9% and 46.9%, respectively.

### Comparative Example 6

Example 1 was repeated except that the evaporation apparatus 10 was not provided with the heating element 20, thereby forming a phosphor layer (cesium bromide layer) on the substrate S. Then, the material utilization efficiency was calculated.

As a result, a material utilization efficiency of 50% was obtained.

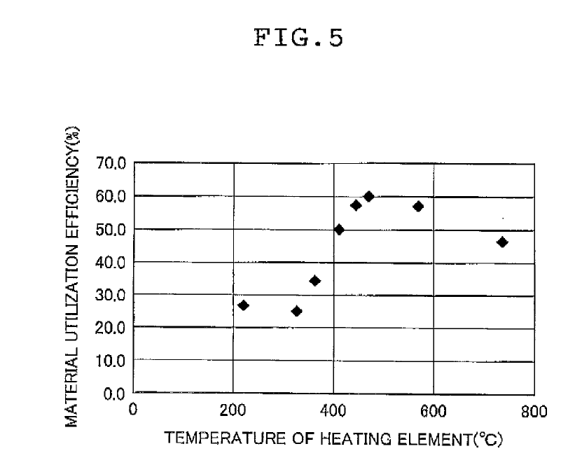

The relation between the temperature of the heating element and the material utilization efficiency is shown in Table 1 below and FIG. 5.

TABLE 1

| | Temperature | Material |
|---|---|---|
| | of heating | utilization |
| | element (° C.) | efficiency (%) |
| Comparative | 218.7 | 26.4 |
| Example 1 | | |
| Comparative | 323.4 | 24.9 |
| Example 2 | | |
| Comparative | 359.4 | 34.3 |
| Example 3 | | |
| Comparative | 409.2 | 49.9 |
| Example 4 | | |
| Example 2 | 443.5 | 57.2 |
| Example 1 | 469 | 59.8 |
| Example 3 | 568 | 57.2 |
| Comparative | 734.8 | 46.9 |
| Example 5 | | |
| Comparative | No heating | 50.0 |
| Example 6 | element | |

As shown in Table 1 and FIG. 5, each of Comparative Examples based on conventional vacuum evaporation methods showed a material utilization efficiency of not more than 50%, whereas each of Examples showed a material utilization efficiency close to 60% according to the invention in which the heating element 20 was provided above the crucible 18 and heated to a temperature which falls within the range of temperatures lower by up to 200° C. than the melting point of the film-forming material (cesium bromide), in other words, within the range of from 436° C. to 636° C. A good material utilization efficiency is achieved compared with conventional vacuum evaporation methods.

The above results clearly show the beneficial effects of the present invention.

What is claimed is:

1. A vacuum evaporation method comprising:
providing a heating element between an evaporation source of a film-forming material and a substrate; and
forming a phosphor layer of an alkali halide-based phosphor on a surface of said substrate by vacuum evaporation while causing said heating element to generate heat at a temperature t (° C.) satisfying Formula (1):
T−200≦t<T (1)
where T is a boiling point (° C.) of said film-forming material.

2. The method of vacuum evaporation according to claim 1, wherein said heating element comprises, when seen from above, plates which are opposed to each other with respect to an outlet for vapors of said film-forming material from said evaporation source.

3. The method of vacuum evaporation according to claim 1, wherein said heating element comprises, when seen from above, a cylinder which surrounds an outlet for vapors of said film-forming material from said evaporation source.

4. The method of vacuum evaporation according to claim 1, wherein said alkali halide-based phosphor contains cesium bromide.

5. The method of vacuum evaporation according to claim 4, wherein said alkali halide-based phosphor further contains europium.
